(19) United States
(12) Patent Application Publication
(10) Pub. No.: US 2015/0041181 A1
(43) Pub. Date: Feb. 12, 2015

(54) PROCESS FOR THE PREPARATION OF PRINTED WIRING BOARD, LAMINATE, LAMINATE FILM AND NON-CURABLE RESIN COMPOSITION USED FOR THE PRINTED WIRING BOARD, AND PRINTED WIRING BOARD PREPARED BY THE PROCESS

(71) Applicant: TAIYO INK MFG. CO., LTD., Hiki-gun (JP)

(72) Inventors: Takayuki CHUJO, Hiki-gun (JP); Arata ENDO, Hiki-gun (JP)

(73) Assignee: TAIYO INK MFG. CO., LTD., Hiki-gun (JP)

(21) Appl. No.: 14/454,182

(22) Filed: Aug. 7, 2014

(30) Foreign Application Priority Data
Aug. 9, 2013 (JP) 2013-165871
May 19, 2014 (JP) 2014-103053

(51) Int. Cl. H05K 1/02; H05K 1/03; H05K 3/18; H05K 3/00; H05K 3/10

(52) U.S. Cl. CPC H05K 1/0296; H05K 3/0017; H05K 3/0032; H05K 3/107; H05K 3/181; H05K 1/036; H05K 2201/09036
USPC 174/250; 216/13; 428/414; 524/562; 526/318.6; 524/611; 528/165

(57) ABSTRACT

A process for the preparation of a printed wiring board that can prevent generation of crack and warpage is provided. A process for the preparation of a printed wiring board, comprising a step of forming a curable resin layer and a non-curable resin layer sequentially on a surface of a substrate; a step of forming depressions in the non-curable resin layer and the curable resin layer from the non-curable resin layer side; a step of applying a catalyst for plating to a surface of the non-curable resin layer and surfaces of the depressions; a step of removing the non-curable resin layer and the catalyst for plating provided on the surface of the non-curable resin layer; and a step of electroless plating the surfaces of the depressions.

### CROSS REFERENCE TO RELATED APPLICATIONS AND INCORPORATION BY REFERENCE

This application is based upon and claims the benefit of priority from the prior Japanese Patent Applications No. 2014-103053 filed on May 19, 2014 and No. 2013-165871 filed on Aug. 9, 2013; the entire content of which is incorporated herein by reference.

### BACKGROUND OF THE INVENTION

1. Field of the Invention

The present invention relates to a process for the preparation of a printed wiring board, particularly relates to a process for the preparation of a printed wiring board which enables the preparation of a flat wiring board. The present invention also relates to a laminate, laminate film, and a non-curable resin composition which can be advantageously utilized for the process, and a printed wiring board prepared by the production process.

2. Description of the Related Art

Recently, a demand for a dense and fine wiring pattern has been increasing in digital apparatuses such as mobile phones, notebook type personal computers, and cameras, in which mother wiring boards have been downsized and thinned.

Packaging techniques such as a semi-additive method and a full-additive method are widely used in a process for the preparation of a wiring board.

The semi-additive method is typically used in a build-up method. In semi-additive method, for example, a substrate is electroless plated with copper; a circuit pattern is formed with a resist; and then the substrate is electrolysis plated with copper to form a copper circuit.

In the full-additive method, after a catalyst is applied to a substrate having blind via holes (via holes), a circuit pattern is formed with a resist. The board is then subjected to only electroless plating with copper to form a copper circuit.

In the semi-additive method and the full-additive method, the circuit is projected from the surface of the substrate. When such substrates are stacked to form a laminate, the surface of the resin between the substrates also has small depressions and projections according to the depressions and projections of the circuit, resulting in an uneven surface of the laminate. These methods make it impossible to reduce widths of lines of the circuit pattern and widths of gaps between lines. For these reasons, these methods are disadvantageous to the preparation of the recent highly dense wiring pattern.

On the other hand, trench-patterned boards without a circuit projected from the surface of a substrate are known. The trench-patterned board is typically produced by the following process: a circuit and depressions (holes or grooves) such as via holes are formed on and in the surface of the substrate with laser. An electroless plated layer is formed on the whole surface of the substrate and then a thick electrolysis plated layer is formed on the surface of electroless plated layer to fill the depressions and form a thick plated layer on the whole surface of the substrate. Subsequently, the plated layer in the region excluding the regions of the depressions is removed by etching or physical polishing. Unfortunately, etching of the plated layer requires a long time, much energy, and huge cost. Buffing may cause distortion or elongation of the substrate and disconnection of the wiring.

Patent Document 1 discloses a process in which an insulating resin is provided on an inner conductive circuit formed on an inner resin layer; the insulating resin is coated with a water-repellent coating resin; the insulating resin coated with the coating resin is processed to form through holes penetrating the coating resin; a catalyst is applied to the insulating resin; and the through holes are filled with a plating metal. In the process, the entire surface of the insulating resin is coated with the coating resin. The catalyst is attached not to the surface of the coating resin but only to the insides of the through holes.

### Patent Document 1: Japanese Patent Laid-Open No. 2010-287862

In the process for the preparation of a printed wiring board described in Patent Document 1, the water-repellent coating layer remains. The differences in the glass transition temperature (Tg) and the coefficient of thermal expansion (CTE) between the water-repellent coating layer and the insulating resin layer underneath cause crack in the coating layer and the insulating resin layer or warpage of the substrate. In the process for the preparation of a printed wiring board, it is difficult to completely prevent the catalyst from being attached to the coating resin, and thus it is difficult to embed the plating metal into only the through holes.

Then, an object of the present invention is to provide a process for the preparation of a printed wiring board which prevents generation of crack and warpage.

Another object of the present invention is to provide a process for the preparation of a printed wiring board which readily produces a trench-wiring board.

Still another object of the present invention is to provide a laminate, a laminate film, and a non-curable resin composition which are advantageous to the production process.

Further another object of the present invention is to provide a printed wiring board prepared by the process.

### SUMMARY OF THE INVENTION

The object can be achieved by a process for the preparation of a printed wiring board, comprising:

a step of forming a non-curable resin layer through a curable resin layer on a surface of a substrate;

a step of forming depressions in the non-curable resin layer and the curable resin layer from the non-curable resin layer side;

a step of applying a catalyst for plating to a surface of the non-curable resin layer and surfaces (wall surfaces and bottom surfaces) of the depressions;

a step of removing the non-curable resin layer and the catalyst for plating provided on the surface of the non-curable resin layer; and a step of electroless plating the surfaces of the depressions.

The curable resin layer is generally cured or half cured before provision of the non-curable resin layer. The curable resin layer may be cured after provision of the non-curable resin layer.

Preferred embodiments of the process for the preparation of a printed wiring board according to the present invention will be listed.

(1) The non-curable resin layer comprises an alkali-soluble resin (alkali-soluble thermoplastic resin).
(2) The alkali-soluble resin has a carboxyl group. In particular, it is preferable that the alkali-soluble resin further have a hydroxyl group.
(3) The alkali-soluble resin has a hydroxyl group.
(4) The non-curable resin layer is removed by alkali development.
(5) The depressions are formed by irradiation with a laser.
(6) The non-curable resin layer comprises a sensitizer having an absorption in the wavelength range of the laser.
(7) The non-curable resin layer comprises a water-repellent additive.

The object can be achieved by

a printed wiring board prepared by the process for the preparation of the printed wiring board.

Furthermore, the object can be achieved by a laminate for a printed wiring board comprising:

a substrate,

a curable resin layer provided on a surface of the substrate, the resin layer being cured, and

a non-curable resin layer provided on the curable resin layer, the non-curable resin layer comprising an alkali-soluble resin;

a laminate film for forming a printed wiring board, comprising:

a film, and

a non-curable resin layer provided on a surface of the film and comprising an alkali-soluble resin;

a non-curable resin composition comprising an alkali-soluble resin, which is used for forming the non-curable resin layer in the process for the preparation of the printed wiring board as mentioned above.

The preferred embodiments of the process for the preparation of a printed wiring board according to the present invention can also be applied to the laminate for the printed wiring board, the laminate film for a printed wiring board, and the non-curable resin composition according to the present invention.

The process for the preparation of the printed wiring board according to the present invention provides printed wiring board, comprising: a substrate, and a curable resin layer formed on a surface of the substrate (the depressions being formed on a surface of the curable resin layer not contacting the surface of the substrate), the resin layer being cured and having depressions formed therein, wherein the depressions in the curable resin layer are filled with a plating metal only by electroless plating.

In the process for the preparation of the printed wiring board according to the present invention, depressions are formed in the curable resin layer and the non-curable resin layer provided in this order on the substrate from the non-curable resin layer side. After the catalyst for plating is applied, the catalyst for plating are removed together with the non-curable resin layer. The surfaces of the depressions having the remaining catalyst for plating are electroless plated to readily prepare a flat wiring board such as a trench-wiring board. In more detail, in the process for the preparation of the printed wiring board of the present invention, only the depressions, which will be wiring and via holes, can be electroless plated by use of the non-curable resin layer removable with an alkali aqueous solution. Accordingly, the process for the preparation of the printed wiring board of the present invention does not leave any unnecessary non-curable resin layer, therefore preventing crack of the curable resin layer and warpage of the substrate. Moreover, flat wiring boards such as trench-wiring boards can be prepared in short time, reduced energy, and low cost.

### BRIEF DESCRIPTION OF THE DRAWINGS

A more complete appreciation of the invention and many of the attendant advantages thereof will be readily perceived as the same becomes better understood by reference to the following detailed description when considered in connection with the accompanying drawings, wherein:

FIG. 1 illustrates a first half of steps in an example of a process for the preparation of a printed wiring board; and

FIG. 2 illustrates a second half of steps in the process for the preparation of a printed wiring board, which is subsequent to the steps shown FIG. 1.

### DETAILED DESCRIPTION OF THE PREFERRED EMBODIMENTS

Other features of this invention will become apparent in the course of the following description of exemplary embodiments, which are given for illustration of the invention and are not intended to be limiting thereof.

Now, a process for the preparation of a printed wiring board according to the present invention, a printed wiring board to be prepared by the process, and a laminate for a printed wiring board, a laminate film for a printed wiring board, and a non-curable resin composition which are advantageous to the above-mentioned process will be described.

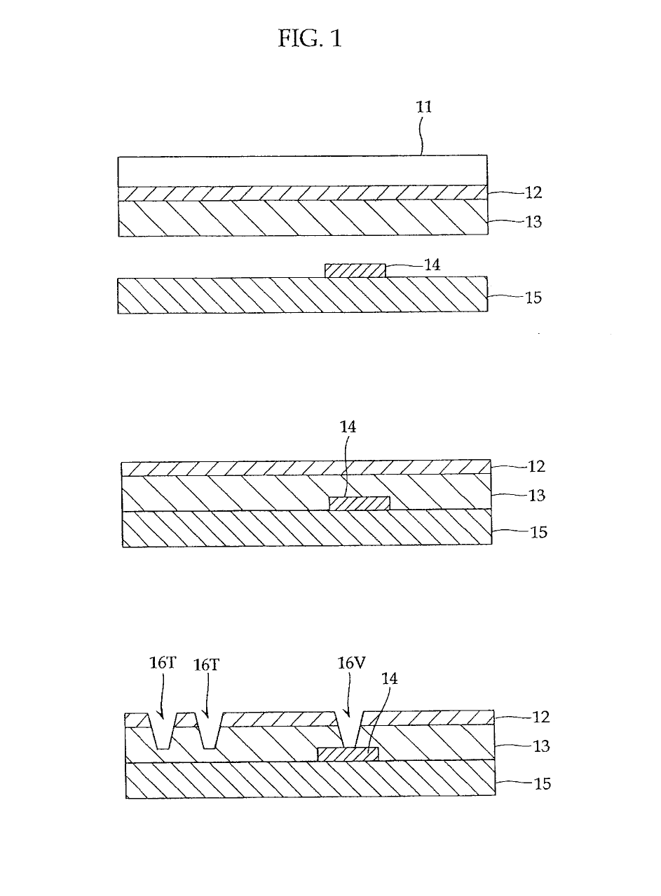

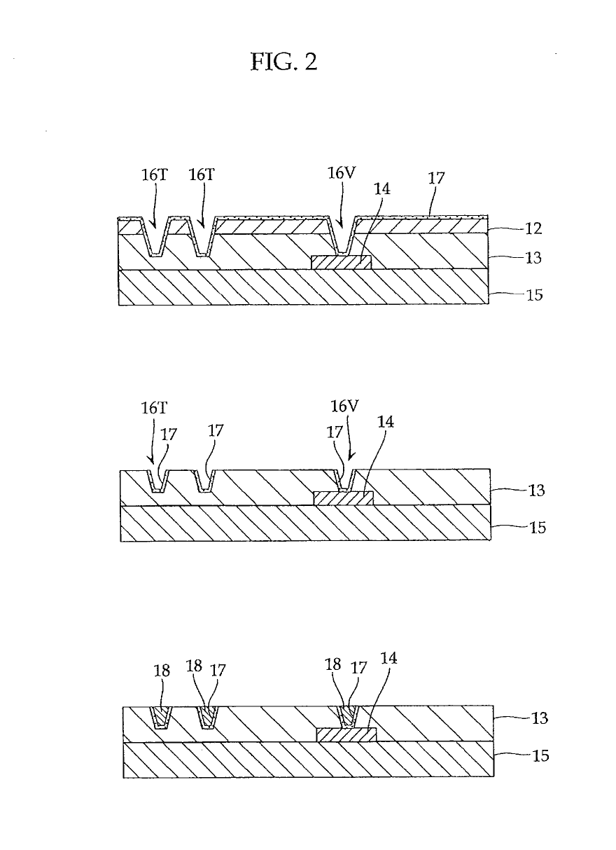

The process for the preparation of a printed wiring board according to the present invention will be described with reference to FIGS. 1 and 2.

### (Laminating Step)

A laminate having a transparent film 11, a non-curable resin layer 12 provided thereon and a curable resin layer 13 provided on non-curable resin layer 12 is prepared The laminate is disposed on a substrate 15 having a conductive layer (conductive circuit) 14 such that the curable resin layer 13 contacts the conductive layer 14. The laminate is pressed against the substrate (Step (1)). After the pressing, the transparent film 11 is removed to prepare a laminate having the substrate 15, the conductive layer 14, the curable resin layer 13, and the non-curable resin layer 12 disposed in this order as shown in Step (2).

In order to provide the non-curable resin layer 12 and the curable resin layer 13, a laminate having the transparent film 11, the non-curable resin layer 12 and the curable resin layer 13 is used. Alternatively, the non-curable resin layer 12 and the curable resin layer 13 can be attached one by one to the substrate 15 when a transparent film 11 having a curable resin layer 13 and a transparent film 11 having a non-curable resin layer 12 are used. Alternatively, the non-curable resin layer 12 and the curable resin layer 13 can be formed on the substrate 15 by applying coating solutions for the respective layers by screen printing, curtain coating, spin coating, dip coating, or roll coating to the substrate 15, and drying the coatings. Alternatively, the non-curable resin layer 12 and the curable resin layer 13 each can be formed on the transparent film 11 by applying coating solutions to the film 11, and evaporating solvents to dry the film 11, and attaching (laminating) the resultant dry film to the substrate 15. The resin layers 12 and 13 can be formed by any method, and the application and drying of the coating solutions may be used in combination with the lamination.

### (Curing Step)

After the curable resin layer 13 is provided and dried, the curable resin layer 13 is heated at approximately 140 to 200° C. for 30 to 90 minutes to be thermally cured, whereby a resin insulating layer is r prepared. The curable resin layer 13 may be half cured or completely cured.

### (Laser Processing Step)

The laminate prepared in Step (2) having the substrate 15, the conductive layer 14, the curable resin layer 13, and the non-curable resin layer 12 provided in this order is irradiated with a laser from the side of the non-curable resin layer 12 to form depressions 16 for forming wiring patterns and via holes (depressions 16T for wiring patterning and depressions 16V for via holes are illustrated in the drawing) (Step (3)).

The depressions 16T and 16V can be formed with a variety of lasers typically used for formation of micro holes. Examples of the lasers can include CO₂ lasers, YAG lasers, and excimer lasers; gas lasers such as argon lasers and helium-neon lasers; and solid lasers such as sapphire lasers. Besides these, dye lasers, semiconductor lasers, and free electron lasers may also be used. Light sources for the UV-YAG lasers and the excimer lasers have an emission wavelength in the range of preferably 180 to 600 nm and light sources for the CO₂ lasers have an emission wavelength of preferably 9.4 to 10.6 μm. In particular, UV-YAG lasers, Nd-YAG lasers, and excimer lasers are preferable because smears barely remain and the takt time can be reduced. These lasers are desirably varied according to the sizes of depressions 16T and 16V to be formed.

The aspect ratios, diameters, and depths of the depressions 16T and 16V are not limited to specific ranges.

### (Desmear Step and Ultrasonic Processing Step)

It is preferred to reave smears produced by laser processing (desmear). The desmear may utilize a wet method or a dry method. Examples of the dry method include plasma etching methods under vacuum and methods using irradiation apparatuses with high pressure lamps, low pressure lamps, metal halide lamps, and ultraviolet light lamps such as xenon lamps. The dry desmear is preferably followed by ultrasonic processing to completely remove smears. Examples of the wet method include a method using a commercially available permanganic acid solution.

### (Simple Removing Step)

The non-curable resin layer may have an end projected to the depression side as a result of the laser processing. In such a case, the projected end is preferably removed by a simple removing method. The removal solution to be used in the removing step described later can also be used. The simple removal step is performed more simply than in the removing method while the time and the temperature are adjusted. This step may be performed after the step of feeding a catalyst.

### (Catalyst Applying Step)

The surface of the laminate on the non-curable resin layer 12 side is composed of the surface of the non-curable resin layer 12 and surfaces (that is, wall surfaces and bottom surfaces) of the depressions 16T and 16V. A catalyst for plating is applied to the surface of the non-curable resin layer 12 and the surfaces of the depressions 16V and 16T (that is, the surface of the laminate on the non-curable resin layer 12 side) to form a catalyst layer 17 for plating (Step (4)). For example, the catalyst layer 17 is formed by a method of applying a coating solution containing divalent palladium ions by spraying and drying the coating or by a method of immersing the laminated in a solution containing the ions.

### (Removing Step)

The non-curable resin layer 12 on the curable resin layer 13 is then removed. The catalyst layer 17 for plating on the non-curable resin layer 12 is also removed together with the non-curable resin layer 12. Thereby, the catalyst layer 17 for plating remains only on the surfaces (that is, wall surfaces and bottom surfaces) of the depressions 16T and 16V (Step (5)). The non-curable resin layer 12 can be removed, for example, with an alkali aqueous solution if the non-curable resin layer 12 is prepared from a synthetic resin having a carboxyl group. Alternatively, the non-curable resin layer 12 can also be removed with an organic solvent. In case of the removal with an alkali aqueous solution, the desmear step may be omitted, and the removal of desmear and the removal of the non-curable resin layer 12 can be performed at the same time. The non-curable resin composition for the non-curable resin layer preferably contains an alkali-soluble resin soluble in an alkali aqueous solution.

### (Plating Step)

To form an electroless plated layer 18 on the remaining catalyst layer 17 for plating on the surfaces of the depressions 16T and 16V, for example, the whole laminate is immersed in an electroless plating solution. This electroless plating results in the depressions 16T and 16V having the catalyst layer 17 for plating and the electroless plated layer 18 formed sequentially on the surfaces (Step (6)).

Apparently from above, in the process according to the present invention, the use of a non-curable resin layer removable by alkali development or the like enables the formation of the catalyst layer for plating only on the depressions which will be wiring patterns and via holes, so that only these depressions can be electroless plated. Accordingly, the process of the present invention can extremely easily prepare a flat wiring board such as trench-wiring boards. In more detail, the process to the present invention is an excellent production process that makes it possible to prepare trench-wiring boards in a short time with reduced energy, and low cost.

The process of the present invention eliminates removal processing of an excessive plated film by physical polishing or etching, preventing disconnection of the wiring caused by etching. For examples, etching is particularly apt to cause disconnection or short circuit in printed wiring boards treating high-speed signals and printed wiring boards with dense wiring. For this reason, the formation of an excessive plated film is not preferable also from the viewpoint of work efficiency and economic efficiency. The process of the present invention prevents formation of such an excessive plated film on the surface of the wiring board, and thus makes it possible to prepare highly reliable printed wiring boards even in those treating high-speed signals and those with high dense wiring.

In a board having a large size of 510×610 mm, for example, warpage of the board or the like lead to difficulties in uniform polishing of the surface of the substrate or etching thereof. Even for this board, the process of the present invention makes it possible to eliminate removal processing of the plating metal excessively adhering to the surface of the substrate, and thus the installation of an extra facility. The process further improve work efficiency and productivity to provide favorable wiring boards having uniform surfaces.

Although only one side of the substrate is shown in the sectional views illustrating the steps in FIGS. 1 and 2, both surfaces of the substrate may be similarly processed. Moreover, these steps can be repeated to prepare a multi-layer printed wiring board having a multi-layer structure.

The substrate 15 is generally composed of a resin having electrical insulation properties, and includes a conductive layer (conductive circuit) 14 attached to the surface thereof. The conductive layer will be a wiring pattern.

Any well known resin can be used for the substrate 15 without being particularly restricted. The substrate 15 may be disposed as a bottom surface (base) of a printed wiring board, and layers may be laminated on one surface of the substrate 15 to prepare a multi-layer printed wiring board. Alternatively, additional insulating layers (such as the substrate above) and conductive layers may be laminated on both surfaces of the substrate 15 to prepare a multi-layer printed wiring board.

The substrate can be a printed wiring board having a circuit thereon or a flexible printed wiring board. Besides these, the followings can be used: copper clad laminates of all grades (such as FR-4) composed of composite materials such as paper-phenol resins, paper-epoxy resins, glass fabric-epoxy resins, glass-polyimide, glass fabric/unwoven fabric-epoxy resins, glass fabric/paper-epoxy resins, synthetic fiber-epoxy resins, fluorinated resin.polyethylene.polyphenylene ether and poly(phenylene oxide).cyanate ester, polyimide films, PET films, glass substrates, ceramic substrates, and wafer plates.

The conductive layer 14 used is a single layer of a metallic foil or multi layers of the metallic foil. The metallic foil is composed of copper, aluminum, iron, nickel, chromium, molybdenum, an alloy thereof (such as copper alloys such as aluminum bronze, phosphorus bronze, and brass), stainless steel, invar, a nickel alloy, or a tin alloy. Further, the single layer of a metallic foil or multi layers of the metallic foil can be prepared by electroless plating or electrolysis plating of the metallic foil. In particular, copper or a copper alloy is preferably used from the viewpoint of adhesion of plating, conductivity, and cost.

Any well known curable resin layer 13 can be laminated on the substrate 15 without being particularly restricted. The curable resin layer may be a thermosetting resin or a photo-curable resin, and is preferably a thermosetting resin.

For the curable resin layer 13 in the present invention, well-known thermosetting resins can be used: for example, amino resin such as melamine resins, benzoguanamine resins, melamine derivatives, and benzoguanamine derivatives; block isocyanate compounds, cyclocarbonate compounds, epoxy compounds, oxetane compounds, episulfide resins, bismaleimide resins, carbodiimide resins, polyimide resins, polyamidimide resins, polyphenylene ether resins, and polyphenylene sulfide resins. In particular, thermosetting resins having a plurality of at least one of cyclic ether groups and cyclic thioether groups (hereinafter, abbreviated into a cyclic (thio)ether group) in the molecule are preferable. The thermosetting resin optionally contains a curing agent. The thermosetting resin having cyclic ether groups such as epoxy compounds is used in combination with a phenol resin, a cyanate ester resin, an active ester resin having a hydroxyl group capped by acetylation, a cyclo-olefin polymer having a carboxyl group, a hydroxyl group, or an active ester structure in the side chain, or a curing agent comprising the curable resin partially having a substituent reactive with a hydroxyl group, a carboxyl group, or a cyclic ether group having an active ester structure.

The thermosetting resin having cyclic (thio)ether groups in the molecule has a plurality of one or two of 3-membered cyclic (thio)ether groups, 4-membered cyclic (thio)ether groups, and 5-membered cyclic (thio)ether groups in the molecule. Examples thereof include compound having a plurality of epoxy groups in the molecule, compounds having a plurality of oxetanyl groups in the molecule, and compounds having a plurality of thioether group in the molecule (namely, episulfide resins). Among these, epoxyfied compounds, i.e., epoxy resins are preferable.

Examples of the epoxyfied compounds (epoxy resins) include bisphenol epoxy resins such as bisphenol A epoxy resins, bisphenol F epoxy resins, bisphenol S epoxy resins, bisphenol E epoxy resins, bisphenol M epoxy resins, bisphenol P epoxy resins, and bisphenol Z epoxy resins; novolak epoxy resins such as bisphenol A novolak epoxy resins, phenol novolak epoxy resins, and cresol novolak epoxy resins; biphenyl epoxy resins, biphenyl aralkyl epoxy resins, aryl alkylene epoxy resins, tetraphenylolethane epoxy resins, naphthalene epoxy resins, anthracene epoxy resins, phenoxy epoxy resins, dicyclopentadiene epoxy resins, norbornene epoxy resins, adamantane epoxy resins, fluorene epoxy resins, glycidyl methacrylate copolymerization epoxy resins, copolymerization epoxy resins of cyclohexylmaleimide and glycidyl methacrylate, epoxy modified polybutadiene rubber derivatives, CTBN-modified epoxy resins, trimethylolpropane polyglycidyl ether, phenyl-1,3-diglycidyl ether, biphenyl-4,4′-diglycidyl ether, 1,6-hexanediol diglycidyl ether, diglycidyl ether of ethylene glycol or propylene glycol, sorbitol polyglycidyl ether, tris(2,3-epoxypropyl)isocyanurate, triglycidyl tris(2-hydroxy ethyl)isocyanurate, and phenoxy resins.

### (Curing Agent)

Examples of the curing agent include phenol resins, polycarboxylic acids and acid anhydrides thereof, cyanate ester resins, and active ester resins. These curing agents may be used alone or in combination.

Known phenol resins can be used: for example, phenol novolak resins, alkyl phenol novolak resins, bisphenol A novolak resins, dicyclopentadiene phenol resins, Xylok phenol resins, terpene-modified phenol resins, cresol/naphthol resins, polyvinyl phenols, phenol/naphthol resins, α-naphthol skeleton-containing phenol resins, and triazine-containing cresol novolak resins. These may be used alone or in combination.

The polycarboxylic acids and acid anhydrides thereof are compounds having two or more carboxyl groups in the molecule and acid anhydrides thereof. Examples thereof include copolymerized products of (meth)acrylic acid, copolymerized products of maleic anhydride, condensates of dibasic acids, and resins having a carboxylic acid terminal such as carboxylic acid terminal imide resins.

The cyanate ester resin is a compound having two or more cyanate ester groups (—OCN) in the molecule. Any known cyanate ester resin can be used. Examples of the cyanate ester resin include phenol novolak cyanate ester resins, alkyl phenol novolak cyanate ester resins, dicyclopentadiene cyanate ester resins, bisphenol A cyanate ester resins, bisphenol F cyanate ester resins, and bisphenol S cyanate ester resins. The cyanate ester resin may be prepolymers partially triazinized.

The active ester resins are resins having two or more active ester groups in the molecule. The active ester resin can be typically prepared by a condensation reaction of a carboxylic acid compound and a hydroxy compound. Among these, active ester compounds prepared from a phenol compound or a naphthol compound as the hydroxy compound are preferable. Examples of the phenol compounds and the naphthol compounds include hydroquinone, resorcin, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzene triol, dicyclopentadienyldiphenol, and phenol novolak.

As the curing agent, an alicyclic olefin polymer may be used. Specific examples of the method of preparing an alicyclic olefin polymer include (1) a method of polymerizing an alicyclic olefin having a carboxyl group and/or a carboxylic anhydride group (hereinafter referred to as “carboxyl group and/or the like”) optionally with an additional monomer, (2) a method of polymerizing an aromatic olefin having a carboxyl group and/or the like optionally with an additional monomer to prepare a (co)polymer, and hydrogenating the aromatic ring portion, (3) a method of copolymerizing an alicyclic olefin having no carboxyl group and/or the like with a monomer having a carboxyl group and/or the like, (4) a method of copolymerizing an aromatic olefin having no carboxyl group and/or the like with a monomer having a carboxyl group and/or the like to prepare a copolymer, and hydrogenating the aromatic ring portion of the copolymer, (5) a method of introducing a compound having a carboxyl group and/or the like into an alicyclic olefin having no carboxyl group and/or the like polymer by a modification reaction, or (6) a method of preparing an alicyclic olefin polymer having a carboxylic acid ester group by the methods (1) to (5), and converting the carboxylic acid ester group into a carboxyl group by hydrolysis or the like.

Such a thermosetting resin (particularly thermosetting resin having a plurality of cyclic thioether groups in the molecule) is preferably compounded in a content of 0.6 to 2.5 equivalents based on 1 equivalent of the functional group of the curing agent. At a content of 0.6 equivalents or more, alkali resistance is high. At a content of 2.5 equivalents or less, the coating has improved strength. The content is more preferably 0.8 to 2.0 equivalents.

The curable resin in the present invention may contain a compound having a plurality of isocyanate groups in the molecule and a compound having a plurality of blocked isocyanate groups in the molecule. Examples of such a compound having a plurality of isocyanate groups or blocked isocyanate groups in the molecule include polyisocyanate compounds or block isocyanate compounds. The blocked isocyanate group is an isocyanate group protected by a reaction with a blocking agent to be temporarily deactivated. When a compound having the blocked isocyanate group is heated to a predetermined temperature, the blocking agent dissociates to generate an isocyanate group. Addition of the polyisocyanate compound or the block isocyanate compound improves curability and the toughness of the cured product.

Such a compound having a plurality of isocyanate groups or blocked isocyanate groups in the molecule is preferably compounded in a content of 0.1 to 50% by mass based on the total composition of the curable resin layer. At a content of 0.1% by mass or more, the coating attains sufficient toughness. At a content of 50% by mass or less, storage stability is improved. The content is more preferably 1 to 30% by mass.

The resin contained in the non-curable resin layer 12 of the present invention is preferably an alkali-soluble resin such as a carboxyl group-containing resin or a phenol resin which is suitable for removal with an alkali. Particularly, resins having a carboxyl group and a hydroxyl group are preferable because these resins can be easily removed with an alkali. Particularly, carboxyl group-containing resins are preferable because these resins can be easily dissolved in a weak alkali such as sodium carbonate.

Examples of the hydroxyl group-containing resin include phenol resins and polyvinyl acetal resins. Known phenol resins can be used: for example, phenol novolak resins, alkyl phenol novolak resins, bisphenol A novolak resins, dicyclopentadiene phenol resins, Xylok phenol resins, terpene-modified phenol resins, cresol/naphthol resins, polyvinylphenols, phenol/naphthol resins, α-naphthol skeleton-containing phenol resins, and triazine-containing cresol novolak resins. These may be used alone or in combination. The polyvinyl acetal resin is particularly preferably a polyvinylbutyral resin. Specific examples of the polyvinyl acetal resin include Denka Butyral 4000-2, 5000-A, 6000-C, and 6000-EP available from DENKI KAGAKU KOGYO KABUSHIKI KAISHA and S-LEC BH series, BX series, KS series, BL series, and BM series available from Sekisui Chemical Co., Ltd. The hydroxyl group-containing resin is preferably a phenol resin from the viewpoint of heat resistance during laser processing.

The carboxyl group-containing resin and acid anhydrides thereof each are a compound having two or more carboxyl groups in the molecule and acid anhydrides thereof. Examples thereof include copolymerized products of (meth)acrylic acid, copolymerized products of maleic anhydride, condensates of dibasic acids, and resins having a carboxylic acid terminal such as carboxylic acid-terminated imide resins. Known commercially available products of carboxylic acid-terminated polyimide resins such as Joncryl (trade name) available from BASF SE Japan Ltd., SMA resin (trade name) available from Sartomer Company, polyazelaic acid anhydride available from New Japan Chemical Co., Ltd., and V-8000 and V-8002 available from DIC Corporation can be used alone or in combination. The hydroxyl group-containing resin may be used in combination with the carboxyl group-containing resin.

Such a carboxyl group-containing resin has many carboxyl groups in the side chain of the polymer backbone (polymer main chain), and therefore the resin can be removed with a diluted alkali aqueous solution.

The carboxyl group-containing resin has an acid value in the range of preferably 40 to 200 mgKOH/g, more preferably 45 to 120 mgKOH/g. The carboxyl group-containing resin having an acid value of 40 mgKOH/g or more can be easily removed with a diluted alkali aqueous solution. The carboxyl group-containing resin having an acid value of 200 mgKOH/g or less has high resistance against wet desmearing.

The weight average molecular weight Mw of the carboxyl group-containing resin varies depending on the resin skeleton. The weight average molecular weight is in the range of typically 2,000 to 150,000, preferably 5,000 to 100,000 in terms of polystyrene. The carboxyl group-containing resin having a weight average molecular weight of 2,000 or more has high tack-free properties. The carboxyl group-containing resin having a weight average molecular weight of 150,000 or less has high alkali develop ability.

The content of the carboxyl group-containing resin to be contained in the non-curable resin layer 12 is in the range of 60 to 100% by mass, preferably 80 to 100% by mass based on the total composition of the non-curable resin layer.

The non-curable resin layer 12 can additionally contain known additives as a water repellent. Any additive known as a water repellent can be added. Examples of the water repellent include silicone-based additives containing Si-based compounds and fluorine-based additives containing F-based compounds. Addition of the water repellent can prevent the catalyst from being applied excessively to the surface of the non-curable resin layer 12, and therefore can reduce the amount of the catalyst to be attached to the surface of the non-curable resin layer 12, leading to ensuring removal of palladium in the step of removing the non-curable resin layer 12. Additionally an antifoaming agent and/or a leveling agent can be contained as other additives to prevent the occurrence of uneven surface of the non-curable resin layer 12 and the reduction in interlayer insulation properties caused by voids or pin holes. Specific examples of the antifoaming agent and/or the leveling agent include commercially available antifoaming agents comprising a non-silicone-based foam-destructive polymer solution such as BYK (registered trademark)-054, BYK-055, BYK-057, and BYK-1790 available from BYK Japan K.K. and silicone-based antifoaming agents such as BYK (registered trademark)-063, BYK-065, BYK-066N, BYK-067A, and BYK-077 available from BYK Japan K.K., and KS-66 (trade name) available from Shin-Etsu Chemical Co., Ltd. Examples of the fluorine-based additives include Megafac series such as Megafac RS, F-554, and F-557 available from DIC Corporation. Such an antifoaming agent and/or a leveling agent is properly compounded in a content of 10 parts by weight or less, preferably 0.01 to 5 parts by weight based on 100 parts by mass of the total composition of the non-curable resin layer 12.

The non-curable resin layer 12 can contain an additional material such as a sensitizer serving as an absorption aid for a laser light source. The sensitizer is preferably a material to be absorbed at the emission wavelength of the laser light source described in the laser processing step. The absorption of the light source at the emission wavelength can be evaluated by checking the absorption with an UV-visible spectrophotometer, an integrating sphere apparatus, or an IR spectrometer. The UV-visible spectrophotometer can measure the absorption wavelength of a glass substrate comprising a glass plate and a non-curable resin composition applied to the glass plate and dried. The IR spectrometer can measure the absorption wavelength of a substrate comprising a KBr plate and a non-curable resin composition applied thereto and dried. When the light source is UV-YAG or an excimer laser, the absorbance determined with ultraviolet-visible spectrophotometer in the range of 180 to 600 nm is in the range of preferably 0.1 to 1.0, more preferably 0.3 to 0.8. When the light source is a CO₂ laser, the absorbance determined with the IR spectrometer in the range of 9.4 to 10.6 μm is in the range of preferably 5 to 95%. The absorbance within the above range can prevent damage caused by the laser, thereby preventing the occurrence of the projected end on the depression side of the non-curable resin layer. Examples of the sensitizer include benzoin compounds, acetophenone compounds, anthraquinone compounds, thioxanthone compounds, ketal compounds, benzophenone compounds, xanthone compounds, and tertiary amine compounds.

Specific examples of the benzoin compounds include benzoin, benzoin methyl ether, benzoin ethyl ether, and benzoin isopropyl ether.

Specific examples of the acetophenone compound include acetophenone, 2,2-dimethoxy-2-phenylacetophenone, 2,2-diethoxy-2-phenylacetophenone, and 1,1-dichloroacetophenone.

Specific examples of the anthraquinone compound include 2-methylanthraquinone, 2-ethylanthraquinone, 2-t-butylanthraquinone, and 1-chloroanthraquinone.

Specific examples of the thioxanthone compound include 2,4-dimethylthioxanthone, 2,4-diethylthioxanthone, 2-chlorothioxanthone, and 2,4-diisopropylthioxanthone.

Specific examples of the ketal compound include acetophenone dimethyl ketal and benzyl dimethyl ketal.

Specific examples of the benzophenone compound include benzophenone, 4-benzoyldiphenyl sulfide, 4-benzoyl-4′-methyldiphenyl sulfide, 4-benzoyl-4′-ethyldiphenyl sulfide, and 4-benzoyl-4′-propyldiphenyl sulfide.

Specific examples of the tertiary amine compound include ethanolamine compounds; and compounds having a dialkylaminobenzene structure, such as dialkylaminobenzophenones (e.g., 4,4′-dimethylaminobenzophenone (NISSOCURE MABP available from NIPPON SODA CO., LTD.) and 4,4′-diethylaminobenzophenone (EAB available from Hodogaya Chemical Co., Ltd.)), coumarin compounds containing a dialkylamino group (e.g., 7-(diethylamino)-4-methyl-2H-1-benzopyran-2-one,(7-(diethylamino)-4-methylcoumarin)), 4-dimethylaminoethyl benzoate (Kayacure EPA available from NIPPON KAYAKU Co., Ltd.), 2-dimethylaminoethyl benzoate (Quantacure DMB available from International Bio-Synthetics Inc.), (n-butoxy)ethyl 4-dimethylamino benzoate (Quantacure BEA available from International Bio-Synthetics Inc.), p-dimethylaminobenzoic acid isoamyl ethyl ester (Kayacure DMBI available from NIPPON KAYAKU Co., Ltd.), 2-ethylhexyl 4-dimethylaminobenzoate (Esolol 507 available from Van Dyk GmbH), and 4,4′-diethylaminobenzophenone (EAB available from Hodogaya Chemical Co., Ltd.).

Such a sensitizer compound (or the total amount of sensitizer compounds if two or more sensitizer compounds are used) is properly compounded in a proportion of preferably 30 parts by mass or less, more preferably 20 parts by mass or less based on 100 parts by mass of the non-curable resin composition.

As described above, the depressions (16T and 16V) are formed so as to penetrate through the non-curable resin layer 12 and penetrate partially or completely through the curable resin layer 13. The depressions (16T and 16V) each represent a via hole for allowing electrical connection between both conductive layers disposed on both surface sides of the substrate 15 or a trench for formation of a wiring pattern. In more detail, the via holes 16V are formed in the curable resin layer 13 so as to penetrate through the non-curable resin layer 12 to expose the conductive layer 14 provided on the substrate 15. The formed via holes 16V are electroless plated to be electrically conductive to the conductive layer 14. The trench 16T is composed of an extending groove and a local via. The trench 16T penetrates through the non-curable resin layer 12 to the middle of the curable resin layer 13. The trench 16T forms a circuit pattern without being electrically connected to the conductive layer 14.

In the production process of the present invention, the depressions 16T and 16V are filled with a plating metal by electroless plating so that the conductive layer 14 is electrically conductive with the surface of the wiring board and a wiring pattern being formed. For this reason, in the present invention, the catalyst for plating is applied to the non-curable resin layer 12 side of the laminate, i.e., the surface of the non-curable resin layer 12 and the surfaces (that is, wall surfaces and bottom surfaces) of the depressions 16T and 16V to form the catalyst layer 17 for plating on the depressions.

For this reason, a predetermined plating pre-treatment is preferably performed. As the pre-treatment, a known method such as the dry or wet desmearing described above and ultrasonic washing can be used.

The catalyst for plating can be applied to the surface of the non-curable resin layer 12 and the surfaces of the depressions 16T and 16V by any method, such as a method using a catalyst solution containing divalent palladium ions (Pd²⁺). The catalyst solution can be a mixed solution of palladium chloride (PdCl₂.2H₂O) of 100 to 300 mg/L in terms of Pd concentration, tin(II) chloride (SnCl₂.2H₂O) of 10 to 20 g/L in terms of Sn concentration, and hydrochloric acid (HCl) of 50 to 250 mL/L. The catalyst layer 17 for plating can be thus disposed.

The catalyst for plating is applied as follows: first, a substrate is immersed in the catalyst solution, for example, at a temperature of 30 to 40° C. for 3 to 10 minutes to adsorb Pd—Sn colloid to the surface of the substrate 15. Subsequently, under a normal temperature condition, the substrate 15 is immersed in 50 to 100 mL/L of sulfuric acid or hydrochloric acid as an accelerator to activate the catalyst. Tin is removed from the complex by the activation to provide palladium adsorption particles, which finally serves as a palladium catalyst to promote deposition of the metal plating by electroless plating.

The non-curable resin layer 12 having the catalyst layer 17 for plating thus formed is removed with a diluted alkali aqueous solution (such as 0.3 to 3 wt % sodium carbonate aqueous solution).

At this time, the non-curable resin layer 12 can be removed by a removing method such as a dipping method, a shower method, a spray method, or a brush method. The removal solution includes alkali aqueous solutions of potassium hydroxide, sodium hydroxide, sodium carbonate, potassium carbonate, sodium phosphate, sodium silicate, TMAH (tetramethylammonium hydroxide), ammonia, and amines.

In the printed wiring board of the present invention, the curable resin layer 13 preferably has a thickness of 5 to 180 μm. The non-curable resin layer 12 has preferably a thickness of 1 to 10 μm, more preferably 1 to 5 μm. In case of a thickness of 1 μm or more, the resistance during dry desmearing and development can be improved. In case of a thickness of 10 μm or less, the trenches and the via holes can be easily formed by laser processing or the non-curable resin layer 12 can be readily removed.

Subsequently, the electroless plated layer 18 is formed on the surfaces of the depressions 16T and 16V having the catalyst layer 17 for plating to prepare a circuit in the printed wiring board. The electroless plated layer 18 is formed on the catalyst layer 17 for plating by electroless plating. The electroless plated layer 18 is provided such that the plating metal is embedded into the depressions 16T and 16V.

Any electroless plating solution can be used in electroless plating without being particularly restricted. Example of the electroless plating solution an electroless include a plating solution containing a water-soluble metal salt such as a water-soluble cupric (alloy) salt and a water-soluble nickel (alloy) salt as the main component; one or more reducing agents (e.g., formaldehyde and/or paraformaldehyde, glyoxylic acid or a salt thereof, hypophosphorous acid or a salt thereof, and dimethylaminoboran; a complexing agent (e.g., tetrasodium ethylenediaminetetraacetate and/or potassium sodium tartrate); and at least one sulfur organic compound.

The production process of the present invention can be used not only in production of a highly dense multi-layer wiring board by the build-up process, but also in the step for the preparation of a multi-layer wiring layer in wafer level CSP (Chip Size Epoxy Package or Chip Scale Epoxy Package) or TCP (Tape Carrier Package), for example.

### EXAMPLES

Specific flows of preparing boards in Examples according to the present invention and Comparative Examples, and evaluation methods will be described.

### <Preparation of Compositions (Inks) for Curable Resin Layer (A Layer) and Non-Curable Resin Layer (B Layer)>

In Examples and Comparative Examples, heat-curable resin compositions and non-curable resin compositions each were prepared by mixing and kneading materials according to formulations shown in Table 1. The numeric values in the tables are expressed in terms of parts by mass unless otherwise specified.

### <Preparation of Dry Film for Curable Resin Layer (A Layer)>

A heat-curable resin composition was applied onto a PET film having a thickness of 38 μm as a carrier film, with an applicator. The coating was dried through a hot air circulating drying furnace at 90° C./10 min to prepare a dry film. The amount of the heat-curable resin layer to be applied was adjusted such that the thickness of the heat-curable resin layer after drying was approximately 20 μm and the content of the solvent in the dry film was 0.3 to 3.0 wt %. The prepared dry film was slit into a predetermined size.

### <Lamination and Curing of Curable Resin Layer (A Layer)>

A double-sided printed wiring board having a pad of copper with a thickness of 5 μm was prepared, and was pre-treated with a CZ-8101 available from MEC COMPANY LTD. The dry film was laminated on both surfaces of the printed wiring board with a Vacuum Laminator MVLP-500 available from Meiki Co., Ltd. to prepare a printed wiring board including a heat-curable resin layer. The lamination was performed at a temperature of 80° C. and a pressure of 5 kg/cm²/60 sec. The carrier film was removed, and the coating was thermally cured with a hot air circulating drying furnace at 180° C./30 min to prepare a double-sided printed wiring board having a cured resin layer (A layer) on both surfaces thereof.

### <Deposition of Non-Curable Resin Layer (B Layer)>

### <DF System>

A non-curable resin composition was applied onto a PET film having a thickness of 38 μm as a carrier film, with an applicator. The coating was dried with a hot air circulating drying furnace at 90° C./10 min to prepare a dry film. The amount of the non-curable resin layer to be applied was adjusted such that the thickness of the non-curable resin layer after drying was approximately 3 μm and the content of the solvent in the dry film was 0.3 to 15 wt %. The prepared dry film was slit into a predetermined size to prepare a dry film of the non-curable resin composition. The dry film was laminated on both surfaces of the double-sided printed wiring board having a cured resin layer with a Vacuum Laminator MVLP-500 available from Meiki Co., Ltd. The PET film was removed from the surfaces of the double-sided printed wiring board to prepare a printed wiring board including a non-curable resin layer (B layer) on both surfaces thereof. The lamination was performed at a temperature of 100° C. and a pressure 5 kg/cm²/60 sec.

### <Application System>

A non-curable resin composition was simultaneously applied onto both surfaces of the double-sided printed wiring board having a cured resin layer with a roll coater available from Furnace, Inc. The coatings were dried with a hot air circulating drying furnace at 90° C./10 min to prepare a double-sided printed wiring board having a non-curable resin layer on both surfaces thereof. The amount of the non-curable resin composition to be applied was adjusted such that the thickness of the non-curable resin composition was approximately 3 μm.

### <Formation of Non-Curable Resin Layer (Polyimide Sheet) in Comparative Example 4>

A double-sided printed wiring board having a pad of copper with a thickness of 5 μm was prepared, and was pre-treated with a CZ-8101 available from MEC COMPANY LTD. The dry film of the heat-curable resin composition was laminated onto both surfaces of a wiring board with an MVLP-500 available from Meiki Co., Ltd. under the following conditions. The PET film was removed to prepare a double-sided printed wiring board having a heat-curable resin layer on both surfaces thereof. A commercially available product, a transparent polyimide film Type HM (thickness: 6.0 μm) available from TOYOBO CO., LTD. was then laminated onto the double-sided printed wiring board with a Vacuum Laminator MVLP-500 available from Meiki Co., Ltd. The polyimide film was thermally cured with a hot air circulating drying furnace at 180° C./60 min to prepare a double-sided wiring board having a UPILEX on both surfaces thereof. The lamination was performed at a temperature of 120° C. and a pressure of 5 kg/cm²/60 sec.

### <Formation of Trench (Via Holes, Lines)>

In the double-sided printed wiring board prepared by the above process and having the cured resin layer 13 and the non-curable resin layer 12 disposed thereon, via holes and lines of a trench pattern were formed with an excimer laser LE-1A (light source XeCl: 308 nm, output: 150 W, line beam scan: 37.5 mm wide) available from Hitachi Via Mechanics, Ltd. By using two chromium masks. First, the printed wiring board was irradiated with a laser to form via holes reaching the surface of the pad. The printed wiring board was scanned with a line beam such that each via hole had a size of 50 μm at the top and 40 μm at the bottom. The mask was replaced to form lines having a groove width of 10 μm and a depth of 10 μm. The depth of the line refers to a depth from the surface of the heat-curable resin layer 12.

### <Evaluation of Laser Processability>

As for the board having the trench pattern (lines and via holes) formed by the process, the shapes of the lines and via holes in the pattern were observed with an optical microscope to evaluate those on the following criteria:

⊚: the trench is formed as designed, and has an even end (not projected).

∘: the trench partially has a projected end caused by melting of the non-curable resin layer.

Δ: the trench has a projected end caused by melting of the non-curable resin layer.

### <Absorbance of B Layer>

A non-curable resin composition was applied onto a glass plate with a spin coater. The coating was dried at 90° C./10 min to form a non-curable resin layer on the glass plate. The amount of the non-curable resin layer to be applied was adjusted such that the thickness of the non-curable resin layer after drying was 5 μm. The absorbance was measured with a UV-visible spectrophotometer and an integrating sphere apparatus. A glass plate equal to the glass plate coated with the non-curable resin composition was measured to determine the absorbance baseline at 500 to 200 nm. The absorbance of the glass plate having the non-curable resin layer was measured, and the absorbance of the dry coating was calculated from the baseline. The target wavelength (308 nm) was found to be equal to the wavelength of the laser light source (excimer laser, light source XeCl: 308 nm). The results of evaluation are shown in Table 2.

### <Desmearing>

### <Permanganic Acid Desmearing (Wet Method)>

As for the double-sided printed wiring board after formation of the trench pattern by processing with a laser, residues on the bottoms of the via holes and smears in the trench were removed with a permanganic acid desmearing aqueous solution.

Smears were removed with a permanganic acid aqueous solution MLB-213 (70° C./5 min) available from Rohm and Haas Company, followed by reduction with an MLB-216 (50° C./5 min).

### <Plasma Desmearing (Dry Method)>

As for the double-sided printed wiring board after formation of the trench pattern, residues on the bottoms of the via holes and smears in the trench were removed with a plasma irradiation apparatus AP-1000 available from March Plasma Systems, Inc. The irradiation was performed under the following conditions: oxygen as gas, degree of vacuum of 150 mtorr, and output of 3 min at 500 W. Smears were completely removed with an ultrasonic washer IUS24 available from Ishii Hyoki Co., Ltd. The conditions were an output of 800 W, a rate of 0.5 m/min, and a process time of 2 min.

### <Application of Catalyst>

After smears were removed by desmearing, a catalyst was applied to the surface layer and the trench formed-portion of the board by the following catalyst feeding process (THRU-CUP series available from C. Uyemura Co., Ltd.). The detailed conditions were as follows:

Cleaner conditioner (THRU-CUP PCK-120-I, 60° C./5 min)

Soft etch (Additive MSE-7, 25° C./2 min)
Washing with sulfuric acid (room temperature/1 min)
Pre-dip (THRU-CUP PED-104, 25° C./1 min)

Activator (mixed solution of THRU-CUP AT-105 and PED104, 30° C./8 min)

### <Evaluation of Palladium Attached>

As for the board in which the catalyst was applied to the surface layer portion of the non-curable resin layer and the trench by the above process, palladium attached was observed visually and with an optical microscope, and was evaluated. The evaluation was performed on the following criteria:

⊚: the surface layer portion of the non-curable resin layer is transparent and the trench formed portion looks black. It turns out that palladium is attached only to the trench formed portion.

∘: the surface layer portion of the non-curable resin layer and the trench formed portion look black. It turns out that palladium is attached not only to the trench formed portion but also to portions other than the trench formed portion.

### <Removability of B Layer>

As for the board to which the catalyst was applied, the non-curable resin layer (B layer) was removed to remove the catalyst on the surface layer portion of the non-curable resin layer (B layer). The removal solution was a 3 wt % alkali aqueous solution (sodium carbonate or sodium hydroxide), and the non-curable resin layer was removed at a spray pressure of 0.2 MPa for 60 sec. After removal, the surface layer portion was observed with an opto-chemical microscope, and was evaluated on the following criteria:

⊚: the non-curable resin layer can be removed both with a sodium carbonate aqueous solution and with a sodium hydroxide aqueous solution.

∘: the non-curable resin layer can be removed only with a sodium hydroxide aqueous solution.

x: the surface layer portion has residues of the non-curable resin layer.

As for the board from which the non-curable resin layer (B layer) was removed, the trench portion was selectively copper plated with an electroless copper plating solution (THRU-CUP series available from C. Uyemura Co., Ltd.). First, the board after the removal was subjected to an accelerator treatment (THRU-CUP AL-106, 25° C./3 min), and the trench portion was completely filled with copper using a high-speed electroless copper plating (THRU-CUP ELC-SP).

### <Plating Deposited on Surface of Board>

The board having the trench portion completely filled by electroless copper plating was observed with an optical microscope and a backscattered electron image to evaluate whether copper plating was deposited on portions other than the trench portion such as the surface layer portion. The evaluation was performed on the following criteria:

∘: copper plating is deposited only on the trench portion (lines and via holes).

x: copper plating is deposited on the trench portion (lines and via holes) and portions other than the trench portion.

### <Evaluation of Heat-Curing Properties: Tg, CTE>

The heat-curable resin layer (A layer, cured at 190° C./60 min) and the commercially available product polyimide sheet (for the B layer) having a thickness of 50 μm were cut to prepare strips having a width of 3 mm and a length of 10 mm, respectively. The glass transition temperature Tg and CTE (coefficient of thermal expansion) were measured and evaluated by a TMA method (tensile method) according to JIS-C-6481. The temperature raising rate was 5° C./min. The coefficient of thermal expansion was evaluated at a temperature not more than Tg. The coefficient of thermal expansion is the average of coefficients of thermal expansion from 25° C. to 100° C., and the unit is ppm. The results are shown in Table 2.

### <Crack Resistance>

The board having the trench portion completely filled by electroless copper plating was evaluated for cooling/heating cycle properties. The board was subjected to 2000 cycles of thermal history, where one cycle was defined as a thermal treatment at −65° C. for 30 min and at 150° C. for 30 min. After the cooling/heating cycle treatment, the surface layer portion was sealed, and was cut with a precision cutter. The cross sections of the via holes and the line portions were observed with an optical microscope. The evaluation was performed on the following criteria. In each wiring pattern, 100 holes were observed.

∘: delamination is not found between copper on the bottomed via holes and the line portions and the curable resin layer.

x: delamination is found between copper on the bottomed via holes and the line portions and the curable resin layer. Delamination was found in the vicinity of the interface between the curable resin layer and the imide layer.

TABLE 1

| | | | | | | | | | | Compar- | Compar- | Compar- | Compar- |
|---|---|---|---|---|---|---|---|---|---|---|---|---|---|
| | | | | | | | | | | ative | ative | ative | ative |
| | | | Exam- | Exam- | Exam- | Exam- | Exam- | Exam- | Exam- | Exam- | Exam- | Exam- | Exam- |
| | | | ple 1 | ple 2 | ple 3 | ple 4 | ple 5 | ple 6 | ple 7 | ple 1 | ple 2 | ple 3 | ple 4 |
| Heat- | Epoxy | jER828 | | | | | | 8.9 | | | 8.9 | | |
| curable | resin | YL7723 | | | | | | | 9.0 | | | 9.0 | |
| resin | | NC-3000L | 5.6 | 5.6 | 5.6 | 5.6 | 5.6 | 8.9 | 4.3 | 5.6 | 8.9 | 4.3 | 5.6 |
| layer | | YX-4000 | 3.0 | 3.0 | 3.0 | 3.0 | 3.0 | | | 3.0 | | | 3.0 |
| (A | | TX0712 | | | | | | | 3.5 | | | 3.5 | |
| layer) | | HP-4032 | 6.0 | 6.0 | 6.0 | 6.0 | 6.0 | | | 6.0 | | | 6.0 |
| | Curing | HPC-9500 | 11.0 | 11.0 | 11.0 | 11.0 | 11.0 | | | 11.0 | | | 11.0 |
| | agent | LA3018 | | | | | | 7.7 | | | 7.7 | | |
| | | EXB9460S | | | | | | 1.8 | | | 1.8 | | |
| | | BA230 | | | | | | | 6.8 | | | 6.8 | |
| | | PT30 | | | | | | | 2.8 | | | 2.8 | |
| | Thermo- | YX6954 | | | | | | 1.5 | 2.2 | | 1.5 | 2.2 | |
| | plastic | FX-293 | 1.5 | 1.5 | 1.5 | 1.5 | 1.5 | | | 1.5 | | | 1.5 |
| | resin | KS-1 | 1.5 | 1.5 | 1.5 | 1.5 | 1.5 | | | 1.5 | | | 1.5 |
| | Rubber | AC-3816N | 2.0 | 2.0 | 2.0 | 2.0 | 2.0 | 2.0 | 2.0 | 2.0 | 2.0 | 2.0 | 2.0 |
| | particle | | | | | | | | | | | | |
| | Flame | HCA-HQ | 2.0 | 2.0 | 2.0 | 2.0 | 2.0 | 2.0 | 2.0 | 2.0 | 2.0 | 2.0 | 2.0 |
| | retardant | | | | | | | | | | | | |
| | Inorganic | SO-C2 | 67.0 | 67.0 | 67.0 | 67.0 | 67.0 | 67.0 | 67.0 | 67.0 | 67.0 | 67.0 | 67.0 |
| | filler | | | | | | | | | | | | |
| | Curing | 2E-4MZ | 0.4 | 0.4 | 0.4 | 0.4 | 0.4 | | | 0.4 | | | 0.4 |
| | acceler- | P200 | | | | | | | 0.2 | | | 0.2 | |
| | ator | 4APy | | | | | | 0.1 | | | 0.1 | | |
| | | NapZn(II) | | | | | | | 0.1 | | | 0.1 | |
| | Organic | Toluene | 5.0 | 5.0 | 5.0 | 5.0 | 5.0 | 7.0 | | 5.0 | 7.0 | | 5.0 |
| | solvent | 2-Methoxy- | | | | | | 3.0 | | | 3.0 | | |
| | | propanol | | | | | | | | | | | |
| | | Cyclo- | 30.0 | 30.0 | 30.0 | 30.0 | 30.0 | 17.5 | 8.0 | 30.0 | 17.5 | 8.0 | 30.0 |
| | | hexanone | | | | | | | | | | | |
| | | Ipzole 150 | 10.0 | 10.0 | 10.0 | 10.0 | 10.0 | | 17.0 | 10.0 | | 17.0 | 10.0 |
| | | MEK | | | | | | 17.5 | 20.0 | | 17.5 | 20.0 | |
| | Total amount (excluding | | 100.0 | 100.0 | 100.0 | 100.0 | 100.0 | 100.0 | 100.0 | 100.0 | 100.0 | 100.0 | 100.0 |
| | solvent, total of only | | | | | | | | | | | | |
| | solid contents) | | | | | | | | | | | | |
| Non- | Alkali- | Joncryl586 | 95.0 | 99.0 | 90.0 | 95.0 | | 95.0 | 95.0 | — | — | — | Trans- |
| curable | soluble | HF-1 | | | | | 95.0 | | | — | — | — | parent |
| resin | resin | | | | | | | | | | | | poly- |
| layer | Additives | EAB | 5.0 | 1.0 | 10.0 | | 5.0 | 5.0 | 5.0 | — | — | — | imide |
| (B | | KS-66 | | | | 5.0 | | | | | | | film |
| layer) | Organic | Cyclo- | 220.0 | 220.0 | 220.0 | 220.0 | 220.0 | 220.0 | 220.0 | — | — | — | (Type |
| | solvent | hexanone | | | | | | | | | | | HM) |

| | | | | | | | |
|---|---|---|---|---|---|---|---|
| Total amount (excluding | 100.0 | 100.0 | 100.0 | 100.0 | 100.0 | 100.0 | 100.0 |
| solvent, total of only | | | | | | | |
| solid contents) | | | | | | | |

TABLE 2

| | | | | | | | | | | Compar- | Compar- | Compar- | Compar- |
|---|---|---|---|---|---|---|---|---|---|---|---|---|---|
| | | | | | | | | | | ative | ative | ative | ative |
| | | | Exam- | Exam- | Exam- | Exam- | Exam- | Exam- | Exam- | Exam- | Exam- | Exam- | Exam- |
| | | | ple 1 | ple 2 | ple 3 | ple 4 | ple 5 | ple 6 | ple 7 | ple 1 | ple 2 | ple 3 | ple 4 |
| Process | Process of laminating | | DF | DF | Appli- | DF | DF | DF | DF | — | — | — | DF |
| of pre- | B layer | | system | system | cation | system | system | system | system | | | | system |
| paring | | | | | system | | | | | | | | |
| board | Desmearing method | | Dry | Wet | Dry | Dry | Dry | Dry | Dry | Wet | Wet | Wet | Dry |
| | | | method | method | method | method | method | method | method | method | method | method | method |
| Absor- | Absorbance of B | | 0.5 | 0.15 | 0.95 | 0.01 | 0.5 | 0.5 | 0.5 | 0.01 | 0.01 | 0.01 | 0.01 |
| bance | layer (308 nm) | | | | | | | | | | | | |
| Items | Evaluation of laser | | ⊚ | ◯ | ◯ | Δ | ⊚ | ⊚ | ⊚ | — | — | — | Δ |
| evalu- | processability | | | | | | | | | | | | |
| ated | Evaluation of | | ◯ | ◯ | ◯ | ⊚ | ◯ | ◯ | ◯ | — | — | — | ◯ |
| | palladium attached | | | | | | | | | | | | |
| | Removability of B | | ⊚ | ⊚ | ⊚ | ⊚ | ◯ | ⊚ | ⊚ | — | — | — | — |
| | layer | | | | | | | | | | | | |
| | Plating deposited on | | ◯ | ◯ | ◯ | ◯ | ◯ | ◯ | ◯ | X | X | X | ◯ |
| | surface of board | | | | | | | | | | | | |
| | Evalua- | Tg (A | 170° C. | 170° C. | 170° C. | 170° C. | 170° C. | 156° C. | 154° C. | 170° C. | 156° C. | 154° C. | 170° C. |
| | tion of | layer) | | | | | | | | | | | |
| | heat | Tg (B | — | — | — | — | — | — | — | — | — | — | 310° C. |
| | curing | layer) | | | | | | | | | | | |
| | proper- | CTE (A | 17 ppm | 17 ppm | 17 ppm | 17 ppm | 17 ppm | 20 ppm | 22 ppm | 17 ppm | 20 ppm | 22 ppm | 17 ppm |
| | ties | layer) | | | | | | | | | | | |
| | | CTE (B | — | — | — | — | — | — | — | — | — | — | 30 ppm |
| | | layer) | | | | | | | | | | | |

| | | | | | | | | | | | |
|---|---|---|---|---|---|---|---|---|---|---|---|
| Crack resistance | ◯ | ◯ | ◯ | ◯ | ◯ | ◯ | ◯ | — | — | — | X |

In Example 1, the board was prepared according to the flow described above and Table 2.

In Example 2, the board was prepared in the same manner as in Example 1 except that the compounding ratio of the composition for the B layer and the desmearing method were changed.

In Example 3, the board was prepared in the same manner as in Example 1 except that the compounding ratio of the composition for the B layer and the lamination method were changed.

In Example 4, the board was prepared in the same manner as in Example 1 except that the additive in the formula for the B layer was replaced with KS-66.

In Example 5, the board was prepared in the same manner as in Example 1 except that the composition for the B layer was changed.

In Example 6, the board was prepared in the same manner as in Example 1 except that the composition for the A layer was changed.

In Example 7, the board was prepared in the same manner as in Example 1 except that the composition for the A layer was changed.

In Comparative Example 1, the board was prepared in the same manner as in Example 1 except that the B layer was not provided, and the treatments accompanied by the disposition of the B layer were not performed.

In Comparative Example 2, the board was prepared in the same manner as in Example 6 except that that the B layer was not provided, and the treatments accompanied by the disposition of the B layer were not performed.

In Comparative Example 3, the board was prepared in the same manner as in Example 7 except that the B layer was not provided, and the treatments accompanied by the disposition of the B layer were not performed.

In Comparative Example 4, the board was prepared according to the process described in Patent Document 1 (Japanese Patent Laid-Open No. 2010-287862).

The following materials were used for the respective layers.

### Heat-Curable Resin Layer (Insulating Resin Layer Before Curing): A Layer 1) Epoxy Resin

| | | Epoxy | Softening | | |
|---|---|---|---|---|---|
| Product | | equivalents | point | | |
| name | Characteristics | (g/eq) | (° C.) | Company | Notes |
| jER828 | Bisphenol A type | 184~194 | Liquid | Mitsubishi Chemical | |
| | | | | Corporation | |
| YL7723 | Bisphenol AF type | 243 | Crystalline | Mitsubishi Chemical | |
| | | | liquid | Corporation | |
| NC-3000L | Biphenyl/phenol | 272 | 52 | NIPPON KAYAKU | |
| | novolak type | | | Co., Ltd. | |
| YX-4000 | Tetramethylbiphenyl | 180~192 | 105 | Mitsubishi Chemical | |
| | type | | | Corporation | |
| TX0712 | Phosphorus- | 355 | | NIPPON STEEL & | Content of |
| | containing epoxy | | | SUMIKIN | phosphorus: |
| | | | | CHEMICAL CO., | 2.6% |
| | | | | LTD. | |
| HP-4032 | Naphthalene type | 145~157 | Semisolid | DIC Cooperation | Semisolid: |
| | | | | | solid at 20° C., |
| | | | | | liquid at 40° C. |

### 2) Curing Agent

| | | | Softening | |
|---|---|---|---|---|
| Product | | | point | |
| name | Characteristics | | (° C.) | Company |
| | | Hydroxyl | | |
| | | equivalents | | |
| | | (g/eq) | | |
| HPC-9500 | α-naphthol | 150 | 110~140 | DIC |
| | skeleton- | | | Cooperation |
| | containing | | | |
| | phenol resin | | | |
| LA3018 | Triazine- | 151 | | DIC |
| | containing | | | Cooperation |
| | cresol novolak | | | |
| | resin | | | |
| | | Active ester | | |
| | | equivalents | | |
| | | (g/eq) | | |
| EXB9460S | Active ester | 223 | | DIC |
| | compound | | | Cooperation |
| | | Cyanate | | |
| | | equivalents | | |
| | | (g/eq) | | |
| BA230 | Bisphenol A | 232 | | Lonza |
| | dicyanate | | | Japan K.K. |
| PT30 | Phenol novolak | 124 | | Lonza |
| | type poly- | | | Japan K.K. |
| | functional | | | |
| | cyanate ester | | | |

### 3) Thermoplastic Resin

| | | Glass | |
|---|---|---|---|
| Product | | transition | |
| name | Characteristics | temperature | Company |
| YX6954 | Phenoxy resin | 130° C. | Mitsubishi |
| | | | Chemical |
| | | | Corporation |
| FX-293 | Fluorene + | 163° C. | Tohto Kasei |
| | tetramethylbiphenyl | | Co., Ltd. |
| | skeleton-containing | | |
| | phenoxy resin | | |
| KS-1 | Polyvinyl | 107° C. | SEKISUI |
| | acetoacetal | | CHEMICAL |
| | | | CO., LTD. |

### 4) Rubber Particle

| Product name | Characteristics | Company |
|---|---|---|
| AC-3816N | Core-shell rubber | Aica Kogyo Company, |
| | particle | Limited |

### 5) Flame Retardant

| Product name | Characteristics | Company |
|---|---|---|
| HCA-HQ | Organic phosphorus compound; | SANKO CO., LTD. |
| | Reactive flame retardant of | |
| | epoxy, polyester, and | |
| | polyurethane | |

### 6) Inorganic Filler

| Product name | Characteristics | Company |
|---|---|---|
| SO-C2 | Spherical silica | Admatechs Company |
| | (average particle | Limited |
| | size 0.5 μm) | |

7) Curing accelerator

| Product name | Characteristics | Company | Notes |
|---|---|---|---|
| 2E-4MZ | 2-Ethyl-4- | SHIKOKU | |
| | methylimidazole | CHEMICALS | |
| | | CORPORATION | |
| P200 | adduct of an | Mitsubishi | |
| | imidazole | Chemical | |
| | compound and | Corporation | |
| | an epoxyfied | | |
| | compound | | |
| 4APy | 4-Aminopyridine | KOEI | |
| | | CHEMICAL | |
| | | CO., LTD. | |
| NapZn(II) | Zinc(II) | Wako Pure | Content of |
| | naphthenate | Chemical | zinc: 8% |
| | mineral spirit | Industries, | |
| | | Ltd. | |

### 8) Organic Solvent

| Name of substance | Boiling point |
|---|---|
| Toluene | b.p. = 110° C. |
| 2-Methoxypropanol | b.p. = 118° C. |
| Cyclohexanone | b.p. = 150° C. |
| Ipzole 150 | b.p. = 184~205° C. |
| MEK (Methyl ethyl ketone) | b.p. = 79.5° C. |

### Coating Layer (Non-Curable Resin Layer): B Layer

| Product | | Acid value | Softening | Molecular | |
|---|---|---|---|---|---|
| name | Characteristics | (mg/KOH) | point (° C.) | weight | Company |
| Joncryl | Styrene-acrylic acid | 108 | 115 | 4600 | BASF SE |
| 586 | copolymer | | | | |
| Product | | Hydroxyl | Softening | | |
| name | Characteristics | equivalents (g/eq) | point (° C.) | Company | |
| HF-1 | Phenol novolak | 104~108 | 82~86 | Meiwa | |
| | | | | Plastic | |
| | | | | Industries, | |
| | | | | Ltd. | |
| Product | | | | | |
| name | Characteristics | Company | | | |
| EAB | 4,4″- | Hodogaya | | | |
| | Diethylaminobenzophenone | Chemical Co., | | | |
| | | Ltd. | | | |
| KS-66 | Silicon-based antifoaming | Shin-Etsu | | | |
| | agent | Chemical Co., | | | |
| | | Ltd. | | | |

Organic solvent: cyclohexanone, the same as above.

### Comparative Example 4

| | | |
|---|---|---|
| High heat-resistant | Transparent | TOYOBO CO., |
| type TT | polyimide film of | LTD. |
| | thickness 6 μm | |

The results of the observations indicate that in Examples 1 to 7, plating is not deposited on the surface of the board, the trench and the via holes are uniformly plated, and the depressions are filled. In Comparative Examples 1 to 3, the coating layer (B layer) is not provided. For this reason, the catalyst on the surface of the resin layer is not removed, and therefore copper plating is deposited on the surface of the resin layer. In Comparative Example 4 using the process described in Patent Document 1, heat resistance is inferior due to the difference in thermal properties between the insulating resin layer (A layer) and the remaining coating layer (B layer).
11 transparent film
12 non-curable resin layer
13 heat-curable resin layer
14 conductive layer
15 substrate
16T, 16V depression
17 catalyst for plating layer
18 electroless plated layer

The present invention being thus described, it will be clearly understood that the same may be varied in many ways. Such variations are not to be regarded as a departure from the spirit and scope of the present invention, and all such modification as would be easily understood to one skilled in the art are intended to be included within the scope of the appended claims.

1. A process for the preparation of a printed wiring board, comprising:
forming a non-curable resin layer through a curable resin layer on a surface of a substrate;
forming depressions in the non-curable resin layer and the curable resin layer from the non-curable resin layer side;
applying a catalyst for plating to a surface of the non-curable resin layer and surfaces of the depressions;
removing the non-curable resin layer and the catalyst for plating provided on the surface of the non-curable resin layer; and
electroless plating the surfaces of the depressions.

2. The process for the preparation of the printed wiring board according to claim 1, wherein the non-curable resin layer comprises an alkali-soluble resin.

3. The process for the preparation of the printed wiring board according to claim 1, wherein the non-curable resin layer comprises a sensitizer having an absorption in the wavelength range of a laser.

4. The process for the preparation of the printed wiring board according to claim 1, wherein the non-curable resin layer comprises a water-repellent additive.

5. A printed wiring board prepared by the process for the preparation of the printed wiring board according to claim 1.

6. A printed wiring board, comprising:
a substrate; and
a curable resin layer formed on a surface of the substrate, the resin layer being cured and having depressions formed therein,
wherein the depressions in the curable resin layer are filled with a plating metal only by electroless plating.

7. A laminate for forming a printed wiring board, comprising:
a substrate;
a curable resin layer provided on a surface of the substrate, the resin layer being cured; and
a non-curable resin layer provided on the curable resin layer, the non-curable resin layer comprising an alkali-soluble resin.

8. A laminate film for forming a printed wiring board, comprising:
a film; and
a non-curable resin layer provided on a surface of the film and comprising an alkali-soluble resin.

9. A non-curable resin composition comprising:
an alkali-soluble resin,
which is used for forming the non-curable resin layer in the process for the preparation of the printed wiring board according to claim 1.

10. The process for the preparation of the printed wiring board according to claim 2, wherein the non-curable resin layer comprises a sensitizer having an absorption in the wavelength range of a laser.

11. The process for the preparation of the printed wiring board according to claim 2, wherein the non-curable resin layer comprises a water-repellent additive.

12. A printed wiring board prepared by the process for the preparation of the printed wiring board according to claim 2.

13. The process for the preparation of the printed wiring board according to claim 3, wherein the non-curable resin layer comprises a water-repellent additive.

14. A printed wiring board prepared by the process for the preparation of the printed wiring board according to claim 3.

15. A printed wiring board prepared by the process for the preparation of the printed wiring board according to claim 4.
